(19) United States
(12) Patent Application Publication
(10) Pub. No.: US 2024/0322777 A1
(43) Pub. Date: Sep. 26, 2024

(54) METHOD FOR PRODUCING COMPOSITE SUBSTRATE

(71) Applicant: NGK INSULATORS, LTD., Nagoya-Shi (JP)

(72) Inventors: Takahiro YAMADERA, Nagoya-Shi (JP); Tsuyoshi IIDA, Fujiyoshida-Shi (JP)

(73) Assignee: NGK INSULATORS, LTD., Nagoya-Shi (JP)

(21) Appl. No.: 18/736,691

(22) Filed: Jun. 7, 2024

Related U.S. Application Data
(63) Continuation of application No. PCT/JP2022/030156, filed on Aug. 5, 2022.

(30) Foreign Application Priority Data
Jan. 17, 2022 (JP) 2022-005286

(51) Int. Cl. H03H 3/10; H03H 9/02; H10N 30/086

(52) U.S. Cl. CPC H03H 3/10; H10N 30/086; H03H 9/02559; H03H 9/02574

(57) ABSTRACT

A method of producing a composite substrate includes: forming a first layer on a lower surface side of a piezoelectric substrate having an upper surface and a lower surface facing each other and having an electrode formed on the lower surface; performing flattening treatment to set a waviness of a surface of the first layer to more than 2 nm and 70 nm or less; and joining a support substrate to a first layer side of the piezoelectric substrate having the first layer formed thereon.

### CROSS-REFERENCE TO RELATED APPLICATIONS

This application is a continuation under 35 U.S.C. 120 of International Application PCT/JP2022/030156 having the International Filing Date of Aug. 5, 2022, and having the benefit of the earlier filing date of Japanese Application No. 2022-005286, filed on Jan. 17, 2022. Each of the identified applications is fully incorporated herein by reference.

### BACKGROUND OF THE INVENTION

### Technical Field

The present invention relates to a method of producing a composite substrate.

### Background Art

A surface acoustic wave (SAW) device has been known as an acoustic wave device utilizing an acoustic wave. For example, the SAW device is used as a filter of a communication device such as a cellular phone. In recent years, with the aim of improving the characteristics of the device, there has been proposed a device having a structure in which a piezoelectric layer is sandwiched between electrodes, and a hollow portion is formed between the piezoelectric layer and a support substrate, as disclosed in Patent Literature 1. Such structure may be obtained, for example, by processing a composite substrate in which a piezoelectric substrate and a support substrate are joined to each other via an intermediate layer.

### CITATION LIST

### Patent Literature

[PTL 1] JP 5650553 B2

### SUMMARY OF THE INVENTION

The composite substrate is required to have durability at the time of its processing. A primary object of the present invention is to provide a composite substrate excellent in durability.

According to an embodiment of the present invention, there is provided a method of producing a composite substrate, including: forming a first layer on a lower surface side of a piezoelectric substrate having an upper surface and a lower surface facing each other and having an electrode formed on the lower surface; performing flattening treatment to set a waviness of a surface of the first layer to more than 2 nm and 70 nm or less; and joining a support substrate to a first layer side of the piezoelectric substrate having the first layer formed thereon.

In one embodiment, at a time of the joining, a joining surface of the first layer and a joining surface on a support substrate side are subjected to activation treatment.

In one embodiment, the activation treatment is performed by plasma irradiation.

In one embodiment, the production method further includes polishing the upper surface of the piezoelectric substrate after the joining.

In one embodiment, the first layer contains silicon oxide.

### Advantageous Effects of Invention

According to the embodiment of the present invention, the composite substrate excellent in durability can be provided.

### BRIEF DESCRIPTION OF THE DRAWINGS

FIG. 1 is a schematic sectional view for illustrating the schematic configuration of a composite substrate according to one embodiment of the present invention.

FIG. 2A is a view for illustrating an example of a production process for a composite substrate according to one embodiment.

FIG. 2B is a view subsequent to FIG. 2A.

FIG. 2C is a view subsequent to FIG. 2B.

FIG. 2D is a view subsequent to FIG. 2C.

FIG. 2E is a view subsequent to FIG. 2D.

FIG. 3A is a view for illustrating an example of a production process for an acoustic wave device according to one embodiment.

FIG. 3B is a view subsequent to FIG. 3A.

FIG. 4 is a graph showing the state of waviness of a surface of a silicon oxide layer in Example 1.

### DESCRIPTION OF EMBODIMENTS

Embodiments of the present invention are described below with reference to the drawings. However, the present invention is not limited to the embodiments. In addition, the drawings may be schematically illustrated in terms of, for example, the width, thickness, and shape of each portion as compared to the embodiments for further making the description clear. However, the drawings are merely examples, and do not limit the interpretation of the present invention.

### A. Composite Substrate

FIG. 1 is a schematic sectional view for illustrating the schematic configuration of a composite substrate according to one embodiment of the present invention. A composite substrate 100 includes a piezoelectric layer 10, an intermediate layer 20, and a support substrate 30 in the stated order. Specifically, the support substrate 30 is arranged on a second main surface 10b side of the piezoelectric layer 10 having a first main surface 10a and a second main surface 10b facing each other, and the intermediate layer 20 is arranged between the support substrate 30 and the piezoelectric layer 10. An electrode 41 is formed on the second main surface 10b of the piezoelectric layer 10, and the intermediate layer 20 is arranged so as to cover the electrode 41. Specifically, the intermediate layer 20 is brought into contact with the electrode 41 and a non-electrode formation region of the piezoelectric layer 10 on which the electrode 41 is prevented from being formed.

The composite substrate 100 may further include any appropriate layer (not shown). The kinds, functions, number, combination, arrangement, and the like of such layers may be appropriately set in accordance with purposes.

The composite substrate 100 may be produced in any appropriate shape. In one embodiment, the substrate may be produced in the form of a so-called wafer. The size of the composite substrate 100 may be appropriately set in accordance with purposes. The diameter of the wafer is, for example, from 100 mm to 200 mm.

### A-1. Piezoelectric Layer

Any appropriate piezoelectric material may be used as the material for forming the piezoelectric layer. A single crystal having the composition of LiAO₃ is preferably used as the piezoelectric material. Herein, A represents one or more kinds of elements selected from the group consisting of: niobium; and tantalum. Specifically, LiAO₃ may be lithium niobate (LiNbO₃), lithium tantalate (LiTaO₃), or a lithium niobate-lithium tantalate solid solution.

In the case where the piezoelectric material is lithium tantalate, for example, when the X-axis (crystal axis) of the piezoelectric material is defined as the direction (X₁) in which a surface acoustic wave propagates, it is preferred that the direction toward which the piezoelectric layer faces when rotated from the Y-axis thereof toward the Z-axis thereof by from 32° to 55° (e.g., 42°) correspond to a direction (X₃) perpendicular to the main surface of the piezoelectric layer, specifically, be (180°, 58° to 35°, 180°) in Euler angle notation.

In the case where the piezoelectric material is lithium niobate, for example, when the X-axis (crystal axis) of the piezoelectric material is defined as the direction (X₁) in which a surface acoustic wave propagates, it is preferred that the direction toward which the piezoelectric layer faces when rotated from the Z-axis thereof toward the −Y-axis thereof by from 0° to 40° (e.g., 37.8°) correspond to a direction (X₃) perpendicular to the main surface of the piezoelectric layer, specifically, be (0°, 0° to 40°, 0°) in Euler angle notation. In addition, in the case where the piezoelectric material is lithium niobate, for example, when the X-axis (crystal axis) of the piezoelectric material is defined as the direction (X₁) in which a surface acoustic wave propagates, it is preferred that the direction toward which the piezoelectric layer faces when rotated from the Y-axis thereof toward the Z-axis thereof by from 40° to 65° correspond to a direction (X₃) perpendicular to the main surface of the piezoelectric layer, specifically, be (180°, 50° to 25°, 180°) in Euler angle notation.

The thickness of the piezoelectric layer may be set to any appropriate thickness in accordance with a use method for the composite substrate and applications thereof. The thickness of the piezoelectric layer is, for example, 0.2 μm or more and 30 μm or less.

### A-2. Electrode

The electrode may be formed of a metal, such as Au, Ag, Al, Pt, Mo, or Ru. Those metals may be used alone or in combination thereof. The thickness of the electrode is, for example, from 0.1 μm to 1 μm.

The electrode is typically formed by forming a metal film on a piezoelectric body through sputtering, vacuum deposition, or the like, and patterning the metal film.

### A-3. Intermediate Layer

For example, silicon oxide (SiO₂), tantalum oxide (Ta₂O₅), niobium oxide (Nb₂O₅), or silicon (PVD-Si) is used as a material for forming the intermediate layer. Silicon oxide is preferably used. The thickness of the intermediate layer (also including a thickness in a region facing the electrode) is, for example, 1 μm or more and 6 μm or less, preferably 2 μm or more and 3 μm or less.

The intermediate layer may be formed by any appropriate method. The intermediate layer may be formed by, for example, physical vapor deposition, such as sputtering or ion beam-assisted deposition (IAD), chemical vapor deposition, or an atomic layer deposition (ALD) method.

### A-4. Support Substrate

Any appropriate substrate may be used as the support substrate. The support substrate may be formed of a single crystalline substance, may be formed of a polycrystalline substance, or may be formed of a combination thereof. A material for forming the support substrate is preferably selected from the group consisting of: silicon; sapphire; glass; quartz; crystal; and alumina.

The silicon may be single crystal silicon having a polycrystalline layer or an amorphous layer formed on a surface thereof, or may be high resistance silicon.

Typically, the sapphire is a single crystalline substance having the composition of Al₂O₃, and the alumina is a polycrystalline substance having the composition of Al₂O₃. The alumina is preferably translucent alumina.

The thermal expansion coefficient of the material for forming the support substrate is preferably smaller than the thermal expansion coefficient of the material for forming the piezoelectric layer. Such support substrate can suppress changes in shape and size of the piezoelectric layer at the time of a temperature change, and hence can suppress, for example, a change in frequency characteristic of a surface acoustic wave device to be obtained.

Any appropriate thickness may be adopted as the thickness of the support substrate. The thickness of the support substrate is, for example, from 100 μm to 1,000 μm.

### A-5. Production Method

A method of producing a composite substrate according to one embodiment of the present invention includes: forming a first layer on a lower surface side of a piezoelectric substrate having an upper surface and a lower surface facing each other and having an electrode formed on the lower surface; flattening the surface of the first layer; and joining a support substrate to a first layer side of the piezoelectric substrate.

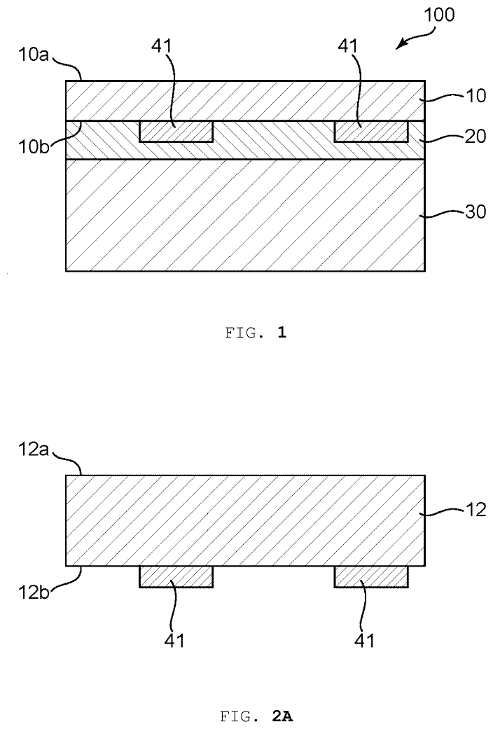

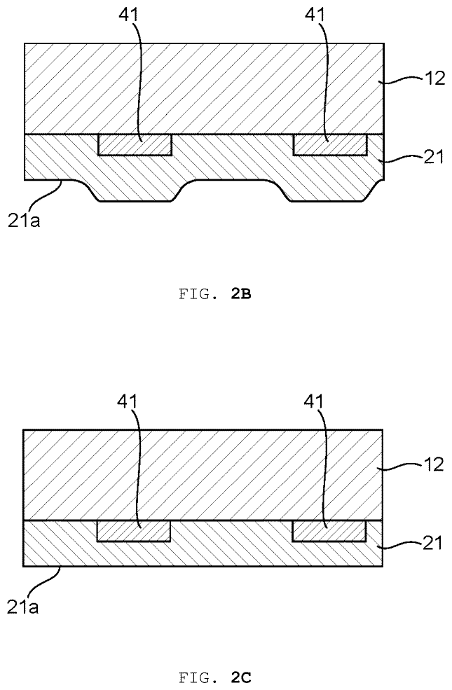

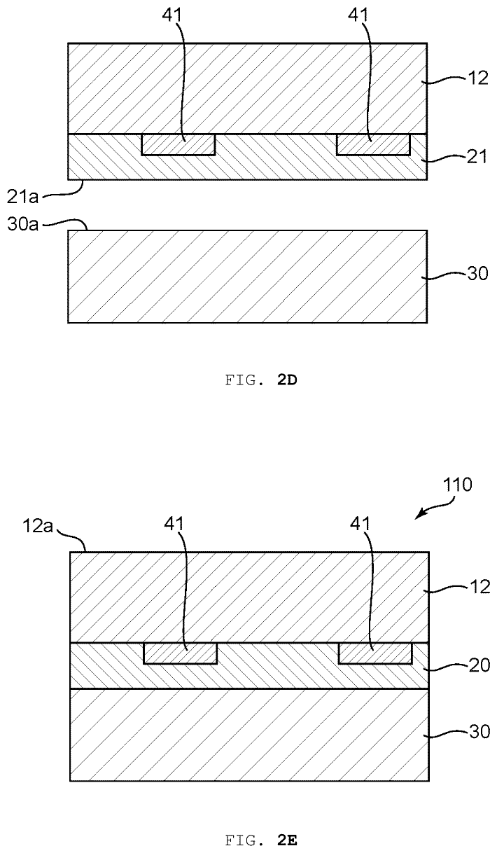

FIG. 2A to FIG. 2E are each a view for illustrating an example of a production process for a composite substrate according to one embodiment.

FIG. 2A is an illustration of a state in which the formation of the electrode 41 on a lower surface 12b of a piezoelectric substrate 12 having an upper surface 12a and the lower surface 12b facing each other is completed, and FIG. 2B is an illustration of a state in which a first layer 21 is formed on a lower surface side of the piezoelectric substrate 12. The first layer 21 may be formed by the above-mentioned film formation method for the intermediate layer. The thickness of the first layer 21 may be set to, for example, such a thickness that the first layer 21 can sufficiently cover the electrode 41. The thickness of the first layer 21 is, for example, 2 μm or more and 6 μm or less.

FIG. 2C is an illustration of a state in which flattening treatment (e.g., lap polishing and/or chemical mechanical polishing) of a surface 21a of the first layer 21 is completed. Through the flattening treatment, the waviness of the surface 21a of the first layer 21 is set to preferably more than 2 nm, more preferably 3 nm or more, still more preferably 5 nm or more. Meanwhile, the waviness of the surface 21a of the first layer 21 is set to preferably 70 nm or less, more preferably 60 nm or less, still more preferably 50 nm or less. The waviness of the surface (surface profile) may be measured with a profiler. The waviness of the surface 21a of the first layer 21 may be controlled through adjustment of the flattening treatment. For example, a value of the waviness may be controlled by adjusting a polishing amount of the lap polishing and a polishing amount of the chemical mechanical polishing.

FIG. 2D is an illustration of a step of joining (directly joining) the piezoelectric substrate 12 having the first layer 21 formed thereon and the support substrate 30. Specifically, the piezoelectric substrate 12 and the support substrate 30 are joined to each other by bringing the joining surface 21a of the first layer 21 and a joining surface 30a of the support substrate 30 into contact with each other. In this manner, as illustrated in FIG. 2E, a composite substrate 110 in which the piezoelectric substrate 12 and the support substrate 30 are joined to each other via the intermediate layer 20 is obtained.

Although not shown, the piezoelectric substrate 12 and the support substrate 30 may be joined to each other by forming a second layer on a side of the support substrate 30 to which the piezoelectric substrate 12 is to be joined, and bringing the joining surface 21a of the first layer 21 formed on the piezoelectric substrate 12 and a joining surface of the second layer formed on the support substrate 30 into contact with each other. In this case, the intermediate layer is formed through joining of the first layer and the second layer. In one embodiment, a material for forming the first layer 21 and a material for forming the second layer are substantially the same. The first layer 21 and the second layer are formed, for example, through sputtering using the same target (e.g., Si target) under the same conditions. Any appropriate material may be selected as each of the material for forming the first layer 21 and the material for forming the second layer as long as the joining can be performed.

When the piezoelectric substrate 12 and the support substrate 30 are brought into contact with each other, the joining surface on a piezoelectric substrate 12 side and the joining surface on a support substrate 30 side are preferably subjected to activation treatment in advance. In one embodiment, the activation treatment is performed by plasma irradiation. A gas in an atmosphere at the time of the activation treatment is, for example, oxygen, nitrogen, hydrogen, or argon. Those gases may be used alone or in combination (as a mixed gas) thereof. Nitrogen is preferably used.

The pressure of the atmosphere at the time of the activation treatment by the plasma irradiation is preferably from 10 kPa to 100 kPa, more preferably from 50 kPa to 80 kPa. Energy at the time of the plasma irradiation is preferably from 30 W to 150 W, more preferably from 60 W to 120 W. The time period of the plasma irradiation is preferably from 5 seconds to 30 seconds.

After the joining surface on the piezoelectric substrate 12 side and the joining surface on the support substrate 30 side are brought into contact with each other, the joined body is preferably heated. Through the heating, joining strength between the piezoelectric substrate 12 and the support substrate 30 can be further increased. A heating temperature is, for example, from 100° C. to 400° C. A heating time period is, for example, from 1 hour to 25 hours. The contact and the heating may each be performed under an inert gas atmosphere, such as nitrogen or argon, or in the atmosphere.

In one embodiment, the heating includes a first heating step and a second heating (annealing) step in the stated order. In the first heating step, the joined body is heated until its temperature increases from room temperature to reach a temperature T1 (e.g., from 100° C. to 150° C.). In the second heating step, the joined body is placed under the condition of a temperature T2 for a predetermined time period (e.g., from 3 hours to 25 hours). The temperature T2 is, for example, 180° C. or more, and may be 200° C. or more, 230° C. or more, 250° C. or more, or 270° C. or more. Meanwhile, the temperature T2 is preferably 350° C. or less, more preferably 300° C. or less from the viewpoint of, for example, preventing the breakage of the joined body. After the second heating step, the joined body is typically naturally cooled.

At the time of the film formation and the joining, an arithmetic average roughness Ra of the surface of each layer is preferably 1 nm or less, more preferably 0.3 nm or less. Such Ra may be achieved, for example, through mirror polishing by chemical mechanical polishing (CMP). The arithmetic average roughness Ra is a value measured with an atomic force microscope (AFM) in a field measuring 10 μm by 10 μm.

At the time of the film formation and the joining, the surface of each layer is preferably washed for, for example, removing the residue of a polishing agent, a work-affected layer, or the like. A method for the washing is, for example, wet washing, dry washing, or scrub washing. Of those, scrub washing is preferred because the surface can be simply and efficiently washed. A specific example of the scrub washing is a method including washing the surface in a scrub washing machine with a detergent (e.g., a SUNWASH series manufactured by Lion Corporation) and then with a solvent (e.g., a mixed solution of acetone and isopropyl alcohol (IPA)).

The upper surface 12a of the piezoelectric substrate 12 of the resultant composite substrate 110 is typically subjected to processing, such as grinding or polishing, so that a piezoelectric layer having the above-mentioned desired thickness may be obtained. In this manner, the composite substrate 100 illustrated in FIG. 1 can be obtained. The adjustment of the joining surface to have the above-mentioned predetermined waviness can make the composite substrate 110 excellent in durability. For example, the composite substrate can be excellent in durability at the time of its processing, such as grinding or polishing. Specifically, the occurrence of peeling in the composite substrate (i.e., peeling at a joining interface) due to the processing, such as grinding or polishing, can be suppressed. As a result, a composite substrate that is free of any peeling and is hence excellent in quality can be obtained.

### B. Use Method

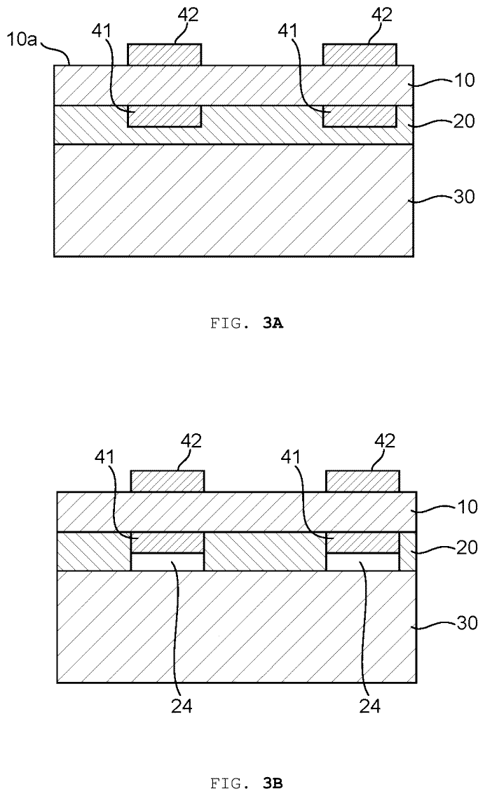

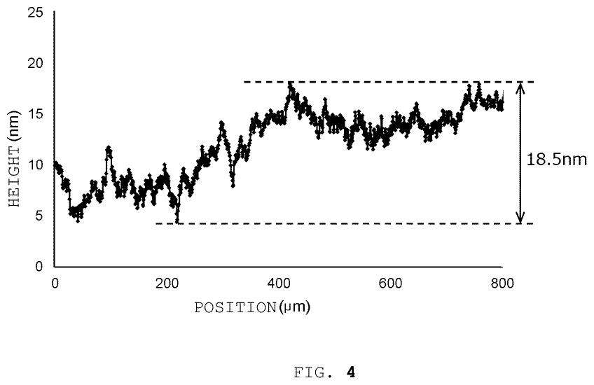

The composite substrate according to the embodiment of the present invention is typically used in an acoustic wave device. FIG. 3A and FIG. 3B are each a view for illustrating an example of a production process for an acoustic wave device according to one embodiment. FIG. 3A is a view for illustrating a state in which the formation of a second electrode (surface electrode) 42 on the surface of the composite substrate 100 (first main surface 10a of the piezoelectric layer 10) is completed. After that, a through hole (not shown) communicating to the intermediate layer 20 is formed in the piezoelectric layer 10, and the intermediate layer 20 is partially etched, for example, by a wet etching method using an etching liquid, to thereby form a hollow portion 24. According to the composite substrate of the embodiment of the present invention, for example, the joining strength between the piezoelectric layer 10 (intermediate layer 20) and the support substrate 30 can be excellent, and hence the hollow portion 24 can be satisfactorily formed.

### EXAMPLES

The present invention is specifically described below by way of Examples. However, the present invention is not limited by these Examples.

### Example 1

A black lithium niobate (LN) substrate having a diameter of 150 mm, having a front surface and a back surface mirror polished, and having a thickness of 0.5 mm was prepared.

In addition, a silicon substrate having a diameter of 150 mm, having a thickness of 0.5 mm, and having high resistance (>2 kΩ·cm) was prepared.

A Au film having a thickness of 2 μm was formed on the LN substrate through sputtering, and then the resultant Au film was patterned (pattern width: 30 μm) through lithography. Thus, an electrode was formed.

Next, a silicon oxide layer (first layer) having a thickness of 5 μm was formed on a pattern formation surface side of the LN substrate. The silicon oxide layer was formed through sputtering of a carousel mode using a Si target (output: 4 KW).

The surface of the silicon oxide layer was subjected to flattening treatment by being polished by 2 μm through lap polishing processing and further polished by 0.5 μm through CMP processing. Thus, the waviness of the surface was set to 18.5 nm as shown in FIG. 4. Herein, the waviness of the surface is a difference between the maximum value and the minimum value of a height measured in the range of 800 μm in the direction along an orientation flat (OF) with a profiler (stylus profiling system, manufactured by Bruker Corporation, model number: “DektakXT (trademark)”) using a measurement probe having a diameter of 12.5 μm.

The surface of the silicon substrate and the surface of the silicon oxide layer of the LN substrate were washed. After that, those substrates were introduced into a plasma activation chamber, and the surface of the silicon substrate and the surface of the silicon oxide layer of the LN substrate were activated. Specifically, activation treatment with nitrogen gas plasma (energy: 100 W) was performed at room temperature for 10 seconds. After that, those substrates were subjected to ultrasonic washing with pure water, and were subjected to spin drying so that particles adhering to their activated surfaces were removed. Next, the respective substrates were aligned, and the activated surfaces of the substrates were superimposed on each other at room temperature in the atmosphere. Thus, a joined body was obtained.

Next, the resultant joined body was loaded into an oven (130° C.) having a nitrogen atmosphere, and was heated for 4 hours. After that, the LN substrate of the joined body (composite substrate) having been taken out of the oven was subjected to grinding and lap polishing, and was further subjected to CMP processing so as to have a thickness of 1 μm. Thus, a composite substrate was obtained.

### Example 2

A composite substrate was obtained in the same manner as in Example 1 except that the waviness of the surface was set to 5 nm by changing the processing conditions of the flattening treatment for the silicon oxide layer on the LN substrate.

### Example 3

A composite substrate was obtained in the same manner as in Example 1 except that the waviness of the surface was set to 50 nm by changing the processing conditions of the flattening treatment for the silicon oxide layer on the LN substrate.

### Comparative Example 1

A composite substrate was obtained in the same manner as in Example 1 except that the waviness of the surface was set to 2 nm by changing the processing conditions of the flattening treatment for the silicon oxide layer on the LN substrate.

### Comparative Example 2

A composite substrate was obtained in the same manner as in Example 1 except that the waviness of the surface was set to 80 nm by changing the processing conditions of the flattening treatment for the silicon oxide layer on the LN substrate.

### <Evaluation>

The composite substrates of Examples and Comparative Examples were subjected to the following evaluations. The evaluation results are summarized in Table 1.

### 1. Bonding Wave

The silicon substrate and the LN substrate after the activation treatment were superimposed on each other, and the substrates were partially pressed to each other. Thus, how the adhesion between the substrates was spontaneously expanded from the pressed site (a so-called bonding wave) was observed.

### 2. Observation of Occurrence of Peeling

The resultant composite substrate was photographed from a LN substrate side with a digital camera, and the ratio of an area in which peeling occurred (able to be visually judged) was determined from the photograph having been taken.

TABLE 1

| | Waviness | | Bonding wave | Peeled area |
|---|---|---|---|---|
| Example 1 | 18.5 | nm | Expanded | 0% |
| | | | concentrically | |
| | | | and slowly from | |
| | | | center portion | |
| Example 2 | 5 | nm | Expanded | 0% |
| | | | concentrically | |
| | | | and slowly from | |
| | | | center portion | |
| Example 3 | 50 | nm | Expanded | 0% |
| | | | concentrically | |
| | | | and slowly from | |
| | | | center portion | |
| Comparative | 2 | nm | Expanded | 10% |
| Example 1 | | | concentrically | |
| | | | and rapidly from | |
| | | | center portion | |
| Comparative | 80 | nm | Not expanded | 5% |
| Example 2 | | | and void | |
| | | | occurred | |

In Comparative Example 1, peeling was observed at a ratio of 10% owing to a load caused by the processing for thinning of the LN substrate. When a cross section of the joined body (before the processing for thinning of the LN substrate) of Comparative Example 1 was observed with a scanning electron microscope (SEM), the formation of a gap was observed at the joining interface (the expansion of the bonding wave was rapid, and a gap was microscopically formed at the joining interface). It is recognized that the cause of the peeling was that sufficient joining strength was not obtained.

In Comparative Example 2, peeling was observed at a site in which the bonding wave was not expanded and a void occurred owing to a load caused by the processing for thinning of the LN substrate.

In each of Examples, it is recognized that the expansion of the bonding wave was slowed down by virtue of the predetermined waviness (unevenness), and the substrates were thus caused to microscopically sufficiently adhere to each other, to thereby achieve high joining strength therebetween.

### INDUSTRIAL APPLICABILITY

Typically, the composite substrate according to the embodiment of the present invention may be suitably used in an acoustic wave device.

What is claimed is:

1. A method of producing a composite substrate, comprising:
forming a first layer on a lower surface side of a piezoelectric substrate having an upper surface and a lower surface facing each other and having an electrode formed on the lower surface;
performing flattening treatment to set a waviness of a surface of the first layer to more than 2 nm and 70 nm or less; and
joining a support substrate to a first layer side of the piezoelectric substrate having the first layer formed thereon.

2. The production method according to claim 1, wherein at a time of the joining, a joining surface of the first layer and a joining surface on a support substrate side are subjected to activation treatment.

3. The production method according to claim 2, wherein the activation treatment is performed by plasma irradiation.

4. The production method according to claim 1, further comprising polishing the upper surface of the piezoelectric substrate after the joining.

5. The production method according to claim 1, wherein the first layer contains silicon oxide.
